(19) United States
(12) Patent Application Publication
(10) Pub. No.: US 2024/0324240 A1
(43) Pub. Date: Sep. 26, 2024

(54) MAGNETIC MEMORY DEVICE AND METHOD OF FABRICATING THE SAME

(71) Applicant: Samsung Electronics Co., Ltd., Suwon-si (KR)

(72) Inventors: Hyungjong JEONG, Suwon-si (KR); Seung Pil KO, Suwon-si (KR); Kyounghun RYU, Suwon-si (KR); Byoungjae BAE, Suwon-si (KR); Kwangil SHIN, Suwon-si (KR)

(73) Assignee: Samsung Electronics Co., Ltd., Suwon-si (KR)

(21) Appl. No.: 18/478,318

(22) Filed: Sep. 29, 2023

(30) Foreign Application Priority Data
Mar. 24, 2023 (KR) 10-2023-0038355

(51) Int. Cl. H10B 61/00; H10N 50/01; H10N 50/20

(52) U.S. Cl. CPC H10B 61/00; H10N 50/01; H10N 50/20

(57) ABSTRACT

A magnetic memory device may include a substrate, a lower interconnection line on the substrate, a data storage structure on the lower interconnection line, and a lower contact plug between the lower interconnection line and the data storage structure and extended in a first direction perpendicular to a top surface of the substrate to connect the lower interconnection line to the data storage structure. An upper portion of the lower contact plug may have a first width in a second direction parallel to the top surface of the substrate, and a lower portion of the lower contact plug may have a second width in the second direction. The first width may be larger than the second width.

### CROSS-REFERENCE TO RELATED APPLICATIONS

This U.S. non-provisional patent application claims priority under 35 U.S.C. § 119 to Korean Patent Application No. 10-2023-0038355, filed on Mar. 24, 2023, in the Korean Intellectual Property Office, the entire contents of which are hereby incorporated by reference.

### BACKGROUND

Various example embodiments relate to a magnetic memory device including a magnetic tunnel junction and/or a method of fabricating the same.

Due to an increasing demand for electronic devices with increased speed and/or reduced power consumption, semiconductor devices require or use faster operating speeds and/or lower operating voltages. Magnetic memory devices have been suggested to satisfy such expectations. For example, the magnetic memory device can provide technical advantages, such as high performance and/or non-volatility, and thus, the magnetic memory devices are emerging as next-generation memory devices.

The magnetic memory device includes a magnetic tunnel junction (MTJ) pattern. The MTJ pattern may include two magnetic layers and an insulating layer interposed therebetween. An electric resistance of the MTJ pattern depends on magnetization directions of the magnetic layers. For example, the resistance of the MTJ pattern is higher when magnetization directions of the magnetic layers are anti-parallel to each other than when they are parallel to each other. This difference in electric resistance can be used for data writing/reading operations of the magnetic memory device.

However, more research is still being pursued to mass-produce the magnetic memory device and satisfy demands or expectations for the magnetic memory device with higher integration density and/or lower power consumption properties.

### SUMMARY

Various example embodiments may provide a magnetic memory device including a lower interconnection line, which is prevented from or is reduced in likelihood of being recessed, and a lower contact plug, in which a void is not formed.

Alternatively or additionally, various example embodiments may provide a magnetic memory device fabricating method, which minimizes or reduces the likelihood of and/or the impact from a recess of a lower interconnection line using a dummy pattern and prevents or reduces the likelihood of and/or the impact from a void from being formed in a lower contact plug.

According to various example embodiments, a magnetic memory device may include a substrate, a lower interconnection line on the substrate, a data storage structure on the lower interconnection line, and a lower contact plug between the lower interconnection line and the data storage structure and extended in a first direction perpendicular to a top surface of the substrate to connect the lower interconnection line to the data storage structure. An upper portion of the lower contact plug may have a first width in a second direction parallel to the top surface of the substrate, and a lower portion of the lower contact plug may have a second width in the second direction. The first width may be larger than the second width.

Alternatively or additionally according to various example embodiments, a method of fabricating a magnetic memory device may include providing a substrate including a cell region and a peripheral region, forming a lower interconnection line on the substrate and a first lower interlayer insulating layer covering the lower interconnection line, sequentially forming a lower insulating layer, a second lower interlayer insulating layer, a first hard mask layer, and a second hard mask layer on the first lower interlayer insulating layer and the lower interconnection line, forming a first trench on the cell region to penetrate the second hard mask layer and the first hard mask layer, forming a second trench on the peripheral region to penetrate the second hard mask layer and an upper portion of the first hard mask layer, with a bottom surface of the second trench being located at a height higher than a bottom surface of the first trench, etching the second lower interlayer insulating layer, which is exposed by the first trench, on the cell region to form a third trench penetrating the second lower interlayer insulating layer, and partially and laterally etching an upper portion of the second lower interlayer insulating layer, which is exposed by an inner side surface of the third trench, to form a fourth trench. The bottom surface of the second trench may be located in the first hard mask layer, after the forming of the fourth trench.

### BRIEF DESCRIPTION OF THE DRAWINGS

FIG. 1 is a circuit diagram illustrating a unit memory cell of a magnetic memory device according to various example embodiments.

FIG. 2 is a plan view illustrating a magnetic memory device according to various example embodiments.

FIG. 3 is a sectional view taken along lines I-I′ and II-II′ of FIG. 2.

FIGS. 4 and 5 are sectional views, each of which illustrates a magnetic tunnel junction pattern of a semiconductor device according to various example embodiments.

FIGS. 6 to 20 are sectional views, which are taken along the lines I-I′ and II-II′ of FIG. 2 to illustrate a method of fabricating a magnetic memory device, according to various example embodiments.

### DETAILED DESCRIPTION

Various example embodiments will now be described more fully with reference to the accompanying drawings, in which some example embodiments are shown.

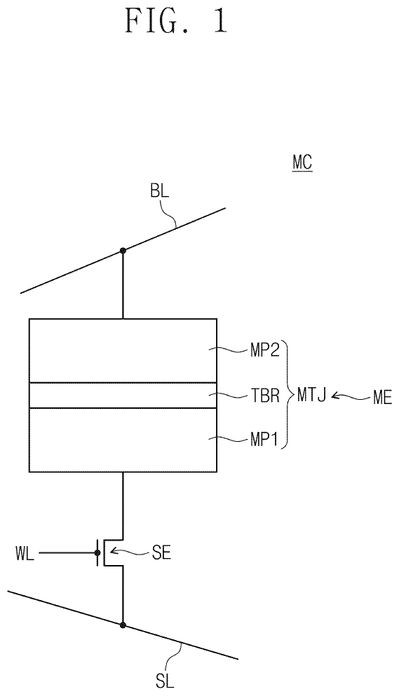

FIG. 1 is a circuit diagram illustrating a unit memory cell of a magnetic memory device according to various example embodiments.

Referring to FIG. 1, a unit memory cell MC may include a memory element ME and a selection element SE. The memory element ME and the selection element SE may be electrically connected to each other in series. The memory element ME may be provided between, and connected to, a bit line BL and the selection element SE. The selection element SE may be provided between, and connected to, the memory element ME and a source line SL and may be controlled by a word line WL. The selection element SE may include, for example, a bipolar transistor and/or a metal-oxide-semiconductor (MOS) field effect transistor, such as planar MOSFET and/or a three-dimensional MOSFET such as an NMOS and/or a PMOS transistor; however, example embodiments are not limited thereto.

The memory element ME may include a magnetic tunnel junction MTJ, and the magnetic tunnel junction MTJ may include a first magnetic pattern MP1, a second magnetic pattern MP2, and a tunnel barrier pattern TBR between the first and second magnetic patterns MP1 and MP2. One of the first and second magnetic patterns MP1 and MP2 may be a fixed magnetic pattern, which has a fixed magnetization direction, regardless of the presence or absence of an external magnetic field, for example as generated under a typical usage environment. The other of the first and second magnetic patterns MP1 and MP2 may be a free magnetic pattern, whose magnetization direction can be changed to one of two stable magnetization directions by an external magnetic field. The electric resistance of the magnetic tunnel junction MTJ may be much greater when the magnetization directions of the fixed and free magnetic patterns are antiparallel to each other than when they are parallel to each other. The electric resistance of the magnetic tunnel junction MTJ may be controlled by changing the magnetization direction of the free magnetic pattern. Thus, a difference in electric resistance of the magnetic tunnel junction pattern MTJ, which is caused by a difference in magnetization direction between the fixed and free magnetic patterns, may be used to store data such as binary data, and the data stored may be changed stored in the unit memory cell MC of the memory device ME, for example, by the external magnetic field applied to the free magnetic pattern.

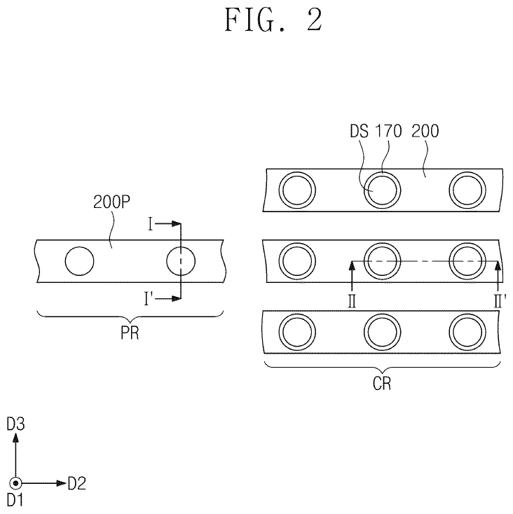

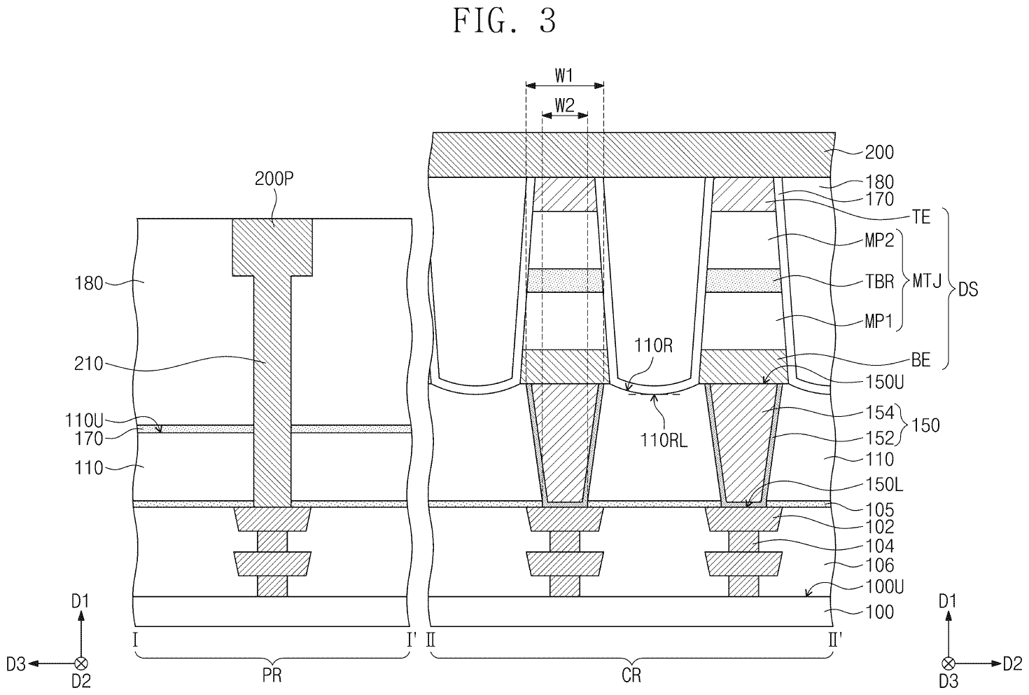

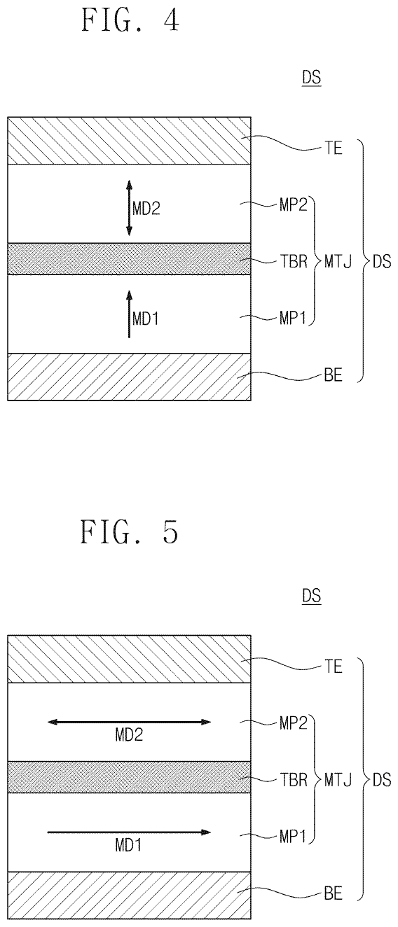

FIG. 2 is a plan view illustrating a magnetic memory device according to various example embodiments. FIG. 3 is a sectional view taken along lines I-I′ and II-II′ of FIG. 2. FIGS. 4 and 5 are sectional views, each of which illustrates a magnetic tunnel junction pattern of a semiconductor device according to various example embodiments.

Referring to FIGS. 2 and 3, a substrate 100 including a cell region CR and a peripheral region PR may be provided. The substrate 100 may be or may be singulated from a semiconductor substrate (e.g., one or more of a silicon wafer, a silicon-on-insulator (SOI) wafer, a silicon germanium wafer, a germanium wafer, or a gallium arsenic wafer). The cell region CR may be a region of the substrate 100 provided with the memory cells MC of FIG. 1, and the peripheral region PR may be another region of the substrate 100, in which peripheral circuits for driving the memory cells MC are provided.

A number of interconnection structures 102 and 104 may be disposed on the substrate 100; although two interconnection structures 102 and 103 are illustrated, example embodiments are not limited thereto. The interconnection structures 102 and 104 may be disposed on the cell and peripheral regions CR and PR of the substrate 100. The interconnection structures 102 and 104 may include lower interconnection lines 102, which are vertically spaced apart from the substrate 100, and lower contacts 104, which are connected to the lower interconnection lines 102. The lower interconnection lines 102 may be spaced apart from the top surface 100U of the substrate 100 in a first direction D1 perpendicular to a top surface 100U of the substrate 100. The lower contacts 104 may be disposed between the substrate 100 and the lower interconnection lines 102, and each of the lower interconnection lines 102 may be electrically connected to the substrate 100 through a corresponding one of the lower contacts 104. The lower interconnection lines 102 and the lower contacts 104 may be formed of or include at least one of metallic materials (e.g., copper such as damascene copper and/or aluminum and/or tungsten).

The selection elements SE of FIG. 1 may be disposed on the substrate 100. For example, the selection elements may be field effect transistors such as NMOS transistors; however, example embodiments are not limited thereto. Each of the lower interconnection lines 102 may be electrically connected to a terminal (e.g., a drain terminal) of a corresponding one of the selection elements through a corresponding one of the lower contacts 104.

A first lower interlayer insulating layer 106 may be disposed on the substrate 100 to cover the interconnection structures 102 and 104. The first lower interlayer insulating layer 106 may be disposed on the cell and peripheral regions CR and PR of the substrate 100. The first lower interlayer insulating layer 106 may be provided to expose top surfaces of the uppermost ones of the lower interconnection lines 102. As an example, a top surface of the first lower interlayer insulating layer 106 may be substantially coplanar with the top surfaces of the uppermost ones of the lower interconnection lines 102. The first lower interlayer insulating layer 106 may be formed of or include at least one of silicon oxide, silicon nitride, and/or silicon oxynitride.

A lower insulating layer 105 may be disposed on the first lower interlayer insulating layer 106 and may cover the exposed top surfaces of the uppermost ones of the lower interconnection lines 102. The lower insulating layer 105 may be disposed on the first lower interlayer insulating layer 106 on the cell region CR and may be extend to a region on the first lower interlayer insulating layer 106 on the peripheral region PR. The lower insulating layer 105 may be thinner than the first lower interlayer insulating layer 106; example embodiments are not limited thereto.

A second lower interlayer insulating layer 110 may be disposed on the lower insulating layer 105. The second lower interlayer insulating layer 110 may be disposed on the lower insulating layer 105 on the cell region CR and may be extended to a region on the lower insulating layer 105 on the peripheral region PR. The lower insulating layer 105 may be interposed between the first lower interlayer insulating layer 106 and the second lower interlayer insulating layer 110, on the cell and peripheral regions CR and PR. The lower insulating layer 105 may be formed of or include a material having an etch selectivity with respect to the first and second lower interlayer insulating layers 106 and 110. For example, the lower insulating layer 105 may be formed of or include silicon nitride (SiCN) and in some example embodiments may not include any of silicon oxide, and/or silicon oxynitride. The second lower interlayer insulating layer 110 may be formed of or include at least one of silicon oxide, silicon nitride, and/or silicon oxynitride and in some example embodiments may not include any SiCN.

Data storage structures DS may be disposed on the second lower interlayer insulating layer 110 on the cell region CR. The data storage structures DS may be spaced apart from each other in a second direction D2 and a third direction D3, which are parallel to the top surface 100U of the substrate 100 and are non-parallel to each other. The data storage structures DS may be arranged in the form of a lattice, such as a triangular lattice and/or a rectangular (e.g., square) lattice; example embodiments are not limited thereto. The second lower interlayer insulating layer 110 on the cell region CR may have a recessed portion 110R, which is formed between the data storage structures DS and is recessed toward the substrate 100. A top surface 110U of the second lower interlayer insulating layer 110 on the peripheral region PR may be located at a height lower than the lowermost surface 110RL of the recessed portion 110R of the second lower interlayer insulating layer 110 on the cell region CR. As used herein, the term ‘height’ may be used to represent a distance from the top surface 100U of the substrate 100 measured in the first direction D1, which is a direction perpendicular to the top surface 100U of the substrate 100.

Lower contact plugs 150 may be disposed in the second lower interlayer insulating layer 110 on the cell region CR and may be spaced apart from each other in the second and third directions D2 and D3. The lower contact plugs 150 may be disposed below the data storage structures DS and may be electrically connected to the data storage structures DS, respectively. The lower contact plug 150 may penetrate the second lower interlayer insulating layer 110 and the lower insulating layer 105 on the cell region CR and may be electrically connected to a corresponding one of the uppermost ones of the lower interconnection lines 102. A bottom surface 150L of the lower contact plug 150 may be in contact with a top surface of the uppermost one of the lower interconnection lines 102. Top surfaces 150U of the lower contact plug 150 may be located at a height higher than or above the lowermost surface 110RL of the recessed portion 110R of the second lower interlayer insulating layer 110 on the cell region CR. The lower contact plug 150 may include a lower contact pattern 154 and a lower barrier pattern 152. The lower contact pattern 154 may be disposed in the second lower interlayer insulating layer 110 and the lower insulating layer 105. The lower barrier pattern 152 may be interposed between a side surface of the lower contact pattern 154 and the second lower interlayer insulating layer 110 and may be extended to a region between a bottom surface of the lower contact pattern 154 and a corresponding one of the lower interconnection lines 102. The lower contact pattern 154 may be formed of or include at least one of doped semiconductor materials (e.g., doped silicon such as doped polysilicon), metallic materials (e.g., one or more of copper, tungsten, titanium, and tantalum), or metal-semiconductor compounds (e.g., metal silicide), and the lower barrier pattern 152 may be formed of or include at least one of conductive metal nitride materials (e.g., one or more of titanium nitride, tantalum nitride, and tungsten nitride). An upper portion of the lower contact plug 150 may have a first width W1 in the second or third direction D2 or D3 parallel to the top surface 100U of the substrate 100. A lower portion of the lower contact plug 150 may have a second width W2 in the second or third direction D2 or D3. The first width W1 may be larger than the second width W2. In some example embodiments, the first width W1 may be 1.3 to 1.5 times the second width W2. Such a width ratio may be advantageous to reduce the propensity of voids.

Each of the data storage structures DS may be disposed on, and electrically connected to, a corresponding one of the lower contact plugs 150. Each of the data storage structures DS may include a bottom electrode BE, a magnetic tunnel junction pattern MTJ, and a top electrode TE, which are sequentially stacked on each of the lower contact plugs 150. The bottom electrode BE may be disposed between each of the lower contact plugs 150 and the magnetic tunnel junction pattern MTJ, and the magnetic tunnel junction pattern MTJ may be disposed between the bottom electrode BE and the top electrode TE. The magnetic tunnel junction pattern MTJ may include the first magnetic pattern MP1, the second magnetic pattern MP2, and the tunnel barrier pattern TBR therebetween. The first magnetic pattern MP1 may be disposed between the bottom electrode BE and the tunnel barrier pattern TBR, and the second magnetic pattern MP2 may be disposed between the top electrode TE and the tunnel barrier pattern TBR. In some example embodiments, the bottom electrode BE may be formed of or include at least one of conductive metal nitride materials (e.g., titanium nitride or tantalum nitride). The top electrode TE may be formed of or include at least one of metallic materials (e.g., Ta, W, Ru, and Ir) or conductive metal nitrides (e.g., TiN).

Referring to FIGS. 4 and 5, the first magnetic pattern MP1 may be a reference layer having a magnetization direction MD1 fixed in a specific direction, and the second magnetic pattern MP2 may be a free layer having a magnetization direction MD2, which can be changed to be parallel or antiparallel to the magnetization direction MD1 of the first magnetic pattern MP1. FIGS. 4 and 5 illustrate an example, in which the second magnetic pattern MP2 is used as the free layer, but embodiments are not limited to this example. Unlike that shown in FIGS. 4 and 5, the first magnetic pattern MP1 may be a free layer, and the second magnetic pattern MP2 may be a reference layer.

Referring to FIG. 4, the magnetization directions MD1 and MD2 of the first and second magnetic patterns MP1 and MP2 may be perpendicular to an interface between the tunnel barrier pattern TBR and the second magnetic pattern MP2. In this case, each of the first and second magnetic patterns MP1 and MP2 may be formed of or include at least one of intrinsic or extrinsic perpendicular magnetic materials. The intrinsic perpendicular magnetic material may include a material exhibiting a perpendicular magnetization property, even when there is no external cause. The intrinsic perpendicular magnetic material may include at least one of i) perpendicular magnetic materials (e.g., one or more of CoFeTb, CoFeGd, and CoFeDy), ii) perpendicular magnetic materials with L1₀ structure, iii) CoPt-based materials with hexagonal-close-packed structure, or iv) perpendicular magnetic structures. The perpendicular magnetic materials with the L1₀ structure may include at least one of L1₀ FePt, L1₀ FePd, L1₀ CoPd, or L1₀ CoPt. The perpendicular magnetic structures may include magnetic and non-magnetic layers that are alternatingly and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n, where n is the number of stacked pairs of the layers. The extrinsic perpendicular magnetic material may include a material, which exhibits an intrinsic in-plane magnetization property when there is no external cause but exhibits a perpendicular magnetization property by an external cause. As an example, the extrinsic perpendicular magnetic material may have a perpendicular magnetization property, due to a magnetic anisotropy that is caused when the first or second magnetic pattern MP1 or MP2 is in contact with the tunnel barrier pattern TBR. The extrinsic perpendicular magnetic material may be formed of or include, for example, CoFeB.

Referring to FIG. 5, the magnetization directions MD1 and MD2 of the first and second magnetic patterns MP1 and MP2 may be parallel to the interface between the tunnel barrier pattern TBR and the second magnetic pattern MP2. In this case, each of the first and second magnetic patterns MP1 and MP2 may be formed of or include a ferromagnetic material. The first magnetic pattern MP1 may further include an antiferromagnetic material fixing a magnetization direction of the ferromagnetic material in the first magnetic pattern MP1.

Each of the first and second magnetic patterns MP1 and MP2 may be formed of or include at least one of Co-based Heusler alloys. The tunnel barrier pattern TBR may be formed of or include at least one of magnesium oxide, titanium oxide, aluminum oxide, magnesium-zinc oxide, or magnesium-boron oxide.

Referring back to FIGS. 2 and 3, a protection insulating layer 170 may be disposed on the second lower interlayer insulating layer 110 on the cell region CR and may cover the recessed portion 110R of the second lower interlayer insulating layer 110 on the cell region CR. The protection insulating layer 170 may be extended to cover the second lower interlayer insulating layer 110 on the peripheral region PR. The protection insulating layer 170 may be extended to cover or enclose a side surface of each of the data storage structures DS, when viewed in a plan view. The protection insulating layer 170 may cover side surfaces of the bottom electrode BE, a magnetic tunnel junction pattern MTR, and the top electrode TE and may be provided to enclose the side surfaces of the bottom electrode BE, the magnetic tunnel junction pattern MTR, and the top electrode TE, when viewed in a plan view.

An upper insulating layer 180 may be disposed on the second lower interlayer insulating layer 110 to enclose the data storage structures DS on the cell region CR and cover the second lower interlayer insulating layer 110 on the peripheral region PR. The upper insulating layer 180 may fill a space between the data storage structures DS. On the cell region CR, the protection insulating layer 170 may be interposed between the side surface of each of the data storage structures DS and the upper insulating layer 180 and may be extended to a space between the recessed portion 110R of the second lower interlayer insulating layer 110 and the upper insulating layer 180. On the peripheral region PR, the protection insulating layer 170 may be interposed between the second lower interlayer insulating layer 110 and the upper insulating layer 180. The upper insulating layer 180 may be formed of or include at least one of silicon oxide, silicon nitride, and/or silicon oxynitride. In various example embodiments, the upper insulating layer 180 may be formed of or include an oxide material, such as tetraethyl orthosilicate (TEOS).

An upper interconnection line 200 may be disposed on the cell region CR. The upper interconnection line 200 may be extended in the second direction D2. The data storage structures DS, which are spaced apart from each other in the second direction D2, may be electrically connected to the upper interconnection line 200. The top electrode TE of the data storage structures DS may be connected to a bottom surface of the upper interconnection line 200, and the topmost surface of the protection insulating layer 170 may be in contact with the bottom surface of the upper interconnection line 200. The upper interconnection line 200 may be electrically connected to the magnetic tunnel junction pattern MTJ through the top electrode TE and may be used as the bit line BL of FIG. 1.

An upper interconnection line contact or via 210 and a peripheral upper interconnection line 200P may be disposed on the peripheral region PR. The peripheral upper interconnection line 200P may be disposed in the upper insulating layer 180 on the peripheral region PR. The upper insulating layer 180 may cover the peripheral upper interconnection line 200P. A top surface of the peripheral upper interconnection line 200P may be exposed to the outside of the upper insulating layer 180. The top surface of the peripheral upper interconnection line 200P may be substantially coplanar with a top surface of the upper insulating layer 180 on the peripheral region PR. The top surface of the peripheral upper interconnection line 200P may be located at a height lower than or below a top surface of the upper interconnection line 200 on the cell region CR. The upper interconnection line contact 210 may be disposed below the peripheral upper interconnection line 200P and may be electrically connected to the peripheral upper interconnection line 200P. The upper interconnection line contact 210 may be in contact with a corresponding one of the peripheral upper interconnection lines 200P without any interface. The upper interconnection line contact 210 and the peripheral upper interconnection line 200P correspond thereto may be connected to each other to form a single object, e.g. a single integrated object without an interface therebetween. The upper interconnection line contact 210 may be provided to penetrate the upper insulating layer 180, the protection insulating layer 170, the second lower interlayer insulating layer 110, and the lower insulating layer 105 and may be electrically connected to a corresponding one of the uppermost ones of the lower interconnection lines 102.

The upper interconnection line 200 and the upper interconnection line contact 210 may include a conductive material and may be formed of or include a metallic material (e.g., copper such as damascene copper). The upper interconnection line 200 and the upper interconnection line contact 210 may be formed of or include the same material, and in some example embodiments may be formed or deposited at the same time.

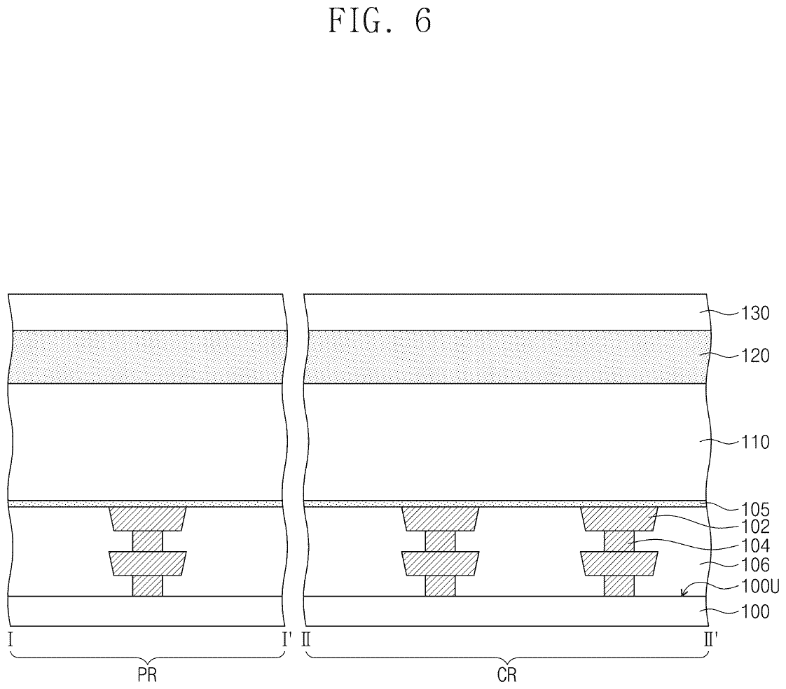

FIGS. 6 to 20 are sectional views, which are taken along the lines I-I′ and II-II′ of FIG. 2 to illustrate a method of fabricating a magnetic memory device, according to various example embodiments. For the sake of brevity, an element previously described with reference to FIGS. 1 to 5 may be identified by the same reference number without repeating an overlapping description thereof.

Referring to FIGS. 2 and 6, the substrate 100 including the cell and peripheral regions CR and PR may be provided. The selection elements SE of FIG. 1 may be formed on the substrate 100, and the interconnection structures 102 and 104 may be formed on the selection elements. The interconnection structures 102 and 104 may be formed on the cell and peripheral regions CR and PR of the substrate 100. Although two metal layers are illustrated in FIG. 6, example embodiments are not limited thereto. The interconnection structures 102 and 104 may include the lower interconnection lines 102 and the lower contacts 104, which are connected to the lower interconnection lines 102. Each of the lower interconnection lines 102 may be electrically connected to a terminal (e.g., a drain terminal) of a corresponding one of the selection elements through a corresponding one of the lower contacts 104. The first lower interlayer insulating layer 106 may be formed on the substrate 100 to cover the interconnection structures 102 and 104. The first lower interlayer insulating layer 106 may be formed to expose top surfaces of the uppermost ones of the lower interconnection lines 102.

The lower insulating layer 105 may be formed on the first lower interlayer insulating layer 106. The lower insulating layer 105 may be formed on the first lower interlayer insulating layer 106 on the cell region CR and may be extended to cover the first lower interlayer insulating layer 106 on the peripheral region PR. The lower insulating layer 105 may cover the exposed top surfaces of the uppermost ones of the lower interconnection lines 102.

The second lower interlayer insulating layer 110, a first hard mask layer 120, and a second hard mask layer 130 may be sequentially formed on the lower insulating layer 105. The second lower interlayer insulating layer 110, the first hard mask layer 120, and the second hard mask layer 130 may be formed on the cell region CR and may be extended to the peripheral region PR. The first hard mask layer 120 may be formed of or include a metal nitride material (e.g., TiN). The second hard mask layer 130 may be formed of or include silicon nitride.

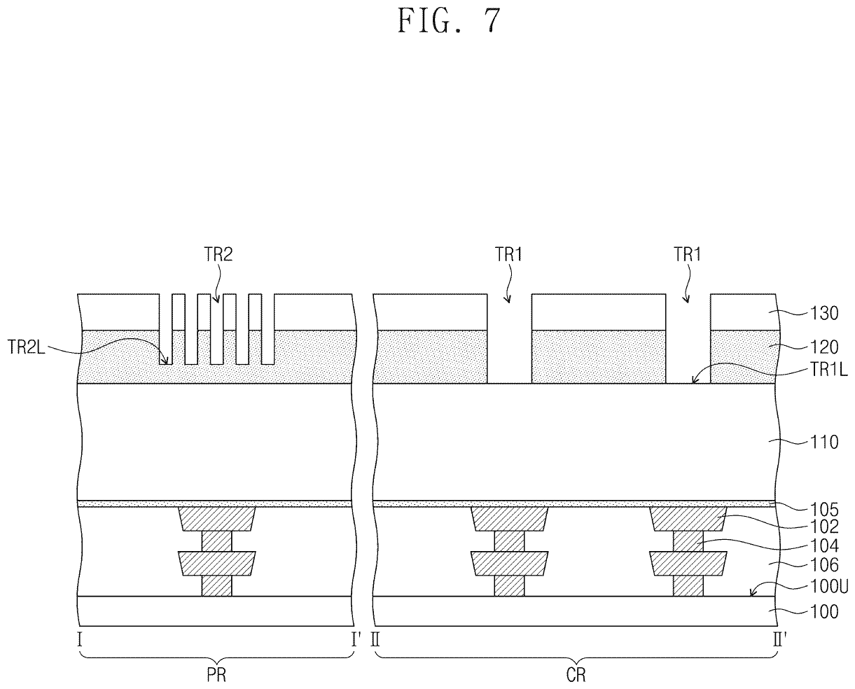

Referring to FIG. 7, a first trench TR1 may be formed on the cell region CR to penetrate the second hard mask layer 130 and the first hard mask layer 120, e.g., with an etching process such as but not limited to a dry etching process. The first trench TR1 may expose a top surface of the second lower interlayer insulating layer 110. A second trench (or dummy pattern) TR2 may be formed on the peripheral region PR to penetrate the second hard mask layer 130 and an upper portion of the first hard mask layer 120. A bottom surface TR2L of the second trench TR2 may be located at a height higher than or above a bottom surface TR1L of the first trench TR1. The bottom surface TR2L of the second trench TR2 may be placed in the first hard mask layer 120, and thus, the top surface of the second lower interlayer insulating layer 110 may not be exposed to the second trench TR2. In some example embodiments, a pitch of the second trenches TR2 in the second direction D2 may be smaller than a pitch of the first trenches TR1 in the second direction. In various example embodiments, the plurality of second trenches TR2 may be formed on the peripheral region PR. Due to the presence of the second trench TR2 formed on the peripheral region PR, it may be possible to relieve or at least partially relieve a phenomenon, in which an etching solution is concentrated to the first trench TR1 in a subsequent etching process, and thereby to prevent or reduce the likelihood of and/or the impact from the lower interconnection line 102 (e.g., the lower interconnection line 102 that is under the second trenches TR2) from being recessed. Accordingly, it may be possible to realize a magnetic memory device with improved electrical and/or reliability characteristics, and/or to increase a yield in a fabrication process.

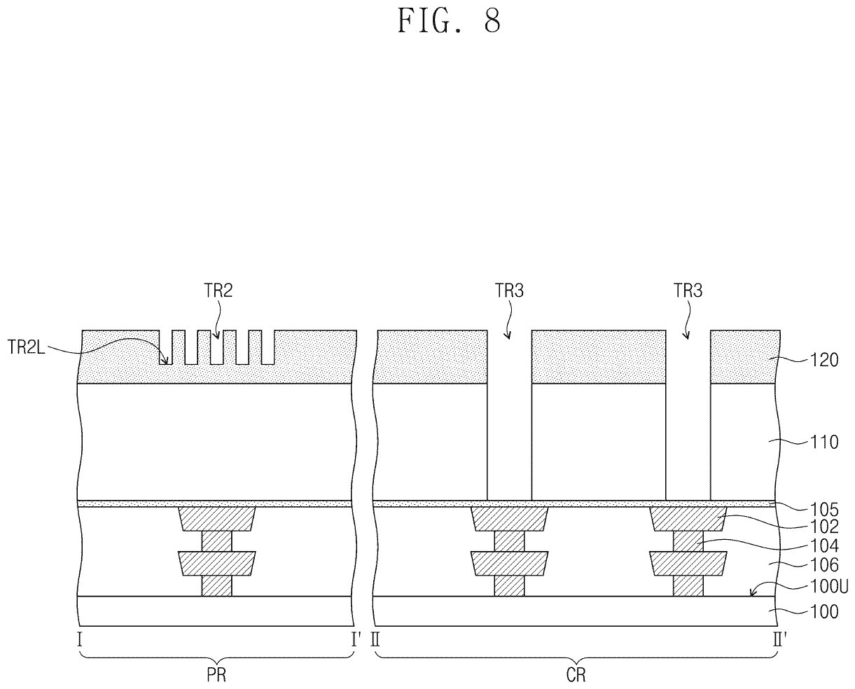

Referring to FIG. 8, the second hard mask layer 130 may be removed from the cell and peripheral regions CR and PR. The second lower interlayer insulating layer 110, which is exposed by the first trench TR1 on the cell region CR, may be etched, e.g., dur etched, to form a third trench TR3 penetrating the second lower interlayer insulating layer 110. The third trench TR3 may be formed to expose a top surface of the lower insulating layer 105.

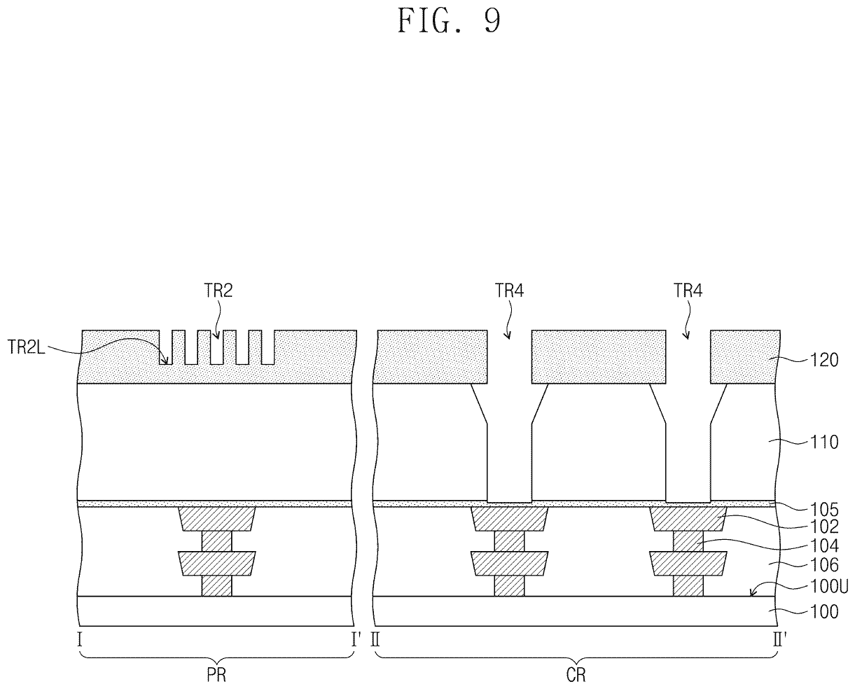

Referring to FIG. 9, a fourth trench TR4 may be formed by laterally etching, e.g., isotropically etching with a wet etchant, an upper portion of the second lower interlayer insulating layer 110, which is exposed by an inner side surface of the third trench TR3 on the cell region CR. The formation of the fourth trench TR4 may be performed through a cleaning process and/or a wet etching process using etching solution such as but not limited to buffered hydrogen fluoride. During the cleaning process, an inner surface of the second trench TR2 may be partially etched, and the bottom surface TR2L of the second trench TR2 may be placed in the first hard mask layer 120, even when the formation of the fourth trench TR4 is finished.

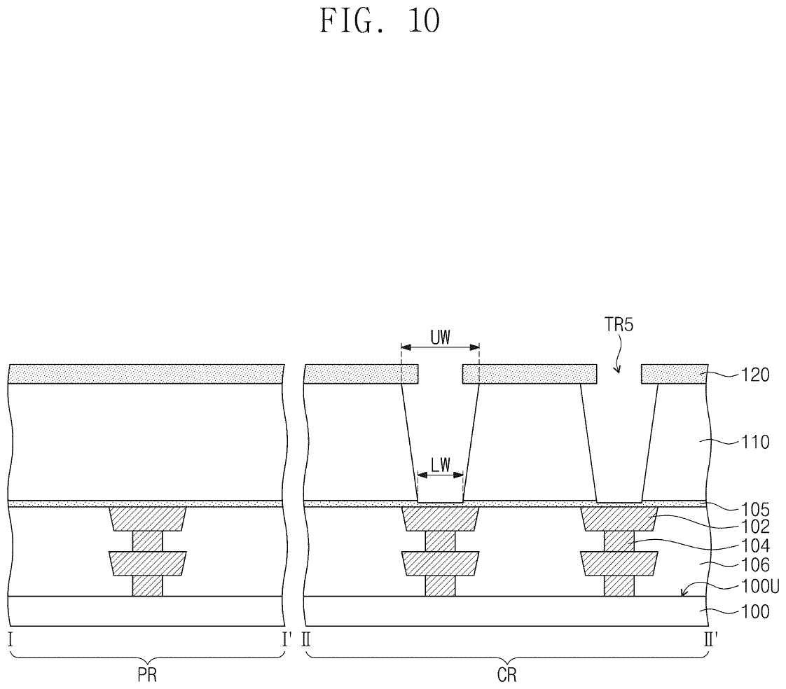

Referring to FIG. 10, the upper portion of the first hard mask layer 120 may be removed (e.g., with a chemical mechanical planarization process), and thus, the second trench TR2 in the first hard mask layer 120 on the peripheral region PR may be removed. A remaining portion of the first hard mask layer 120 may be left on the second lower interlayer insulating layer 110 on the cell and peripheral regions CR and PR. A fifth trench TR5 may be formed by laterally etching a portion of the second lower interlayer insulating layer 110, which is exposed by an inner side surface of the fourth trench TR4. The formation of the fifth trench TR5 may be performed through a cleaning process, in which HF-containing or BHF-containing etching solution is used. The fifth trench TR5 may have a width in the second direction D2 parallel to the top surface 100U of the substrate 100, and a width UW of an upper portion of the fifth trench TR5 may be larger than a width LW of a lower portion of the fifth trench TR5. Since the fifth trench TR5 is formed to have the width UW larger than the width LW, the fifth trench TR5 may be more easily filled with a metallic material in a subsequent metal deposition process to form the lower contact plug 150. Accordingly, it may be possible to prevent or reduce the likelihood of and/or the impact form a void from being formed in the lower contact plug 150 and consequently to realize a magnetic memory device with improved electrical and reliability characteristics and increase a yield in a fabrication process.

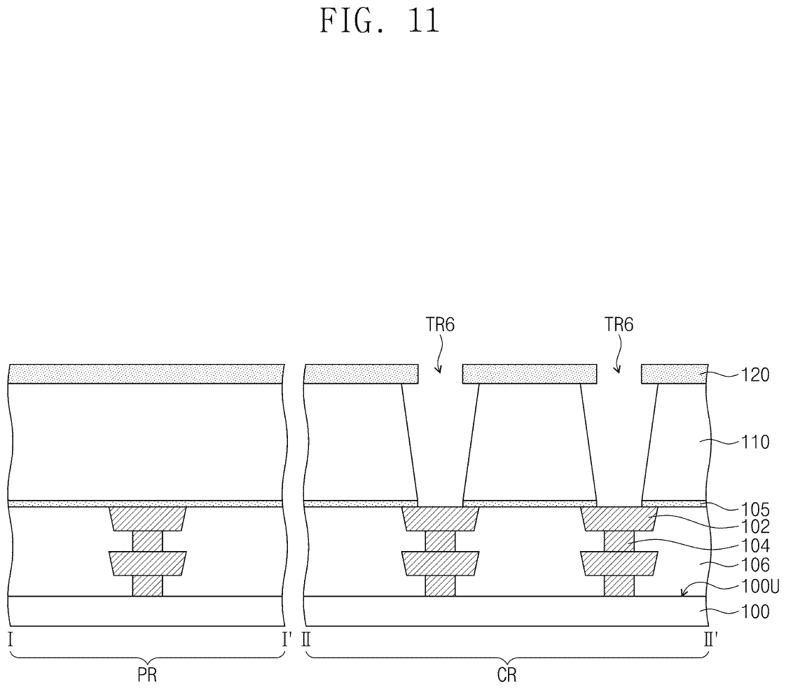

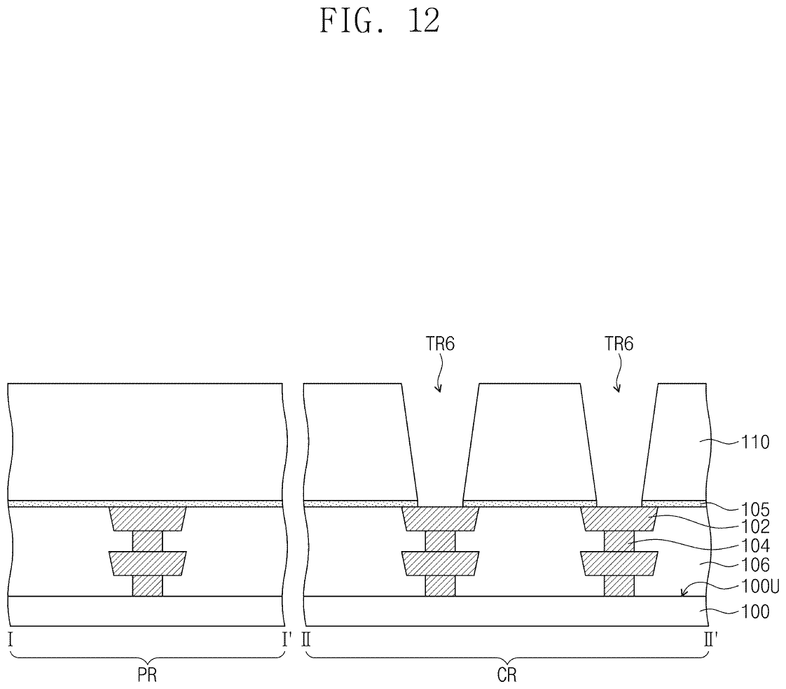

Referring to FIGS. 11 and 12, the lower insulating layer 105 exposed by the fifth trench TR5 on the cell region CR may be removed by an etching process, and as a result, a sixth trench TR6 may be formed. The sixth trench TR6 may expose top surfaces of the uppermost ones of the lower interconnection lines 102 on the cell region CR. Thereafter, the first hard mask layer 120 may be removed from the cell and peripheral regions CR and PR. The removal of the first hard mask layer 120 may be performed through a cleaning process of removing a metallic hard mask layer; example embodiments are not limited thereto.

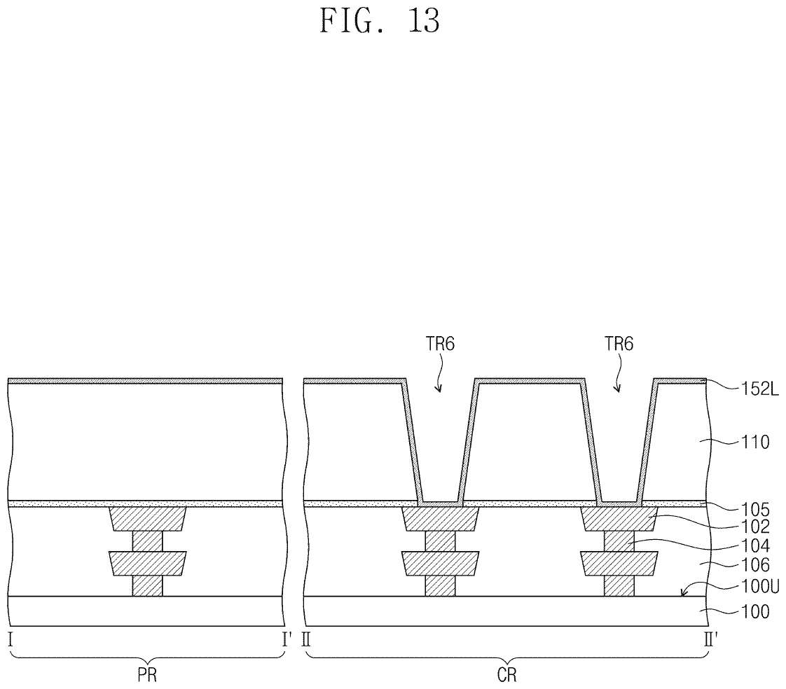

Referring to FIG. 13, a lower barrier pattern layer 152L may be formed to fill a portion of the sixth trench TR6. The lower barrier pattern layer 152L may be formed using a deposition process having a good step coverage property, such as one or more of a chemical vapor deposition (CVD) process, a physical vapor deposition (PVD) process, or an atomic layer deposition (ALD) process. The lower barrier pattern layer 152L may conformally cover an inner side surface and a bottom surface of the sixth trench TR6. The lower barrier pattern layer 152L may be extended to the top surface of the second lower interlayer insulating layer 110 on the cell and peripheral regions CR and PR. The lower barrier pattern layer 152L may be formed of or include at least one of metal nitride materials (e.g., TaN and/or TiN).

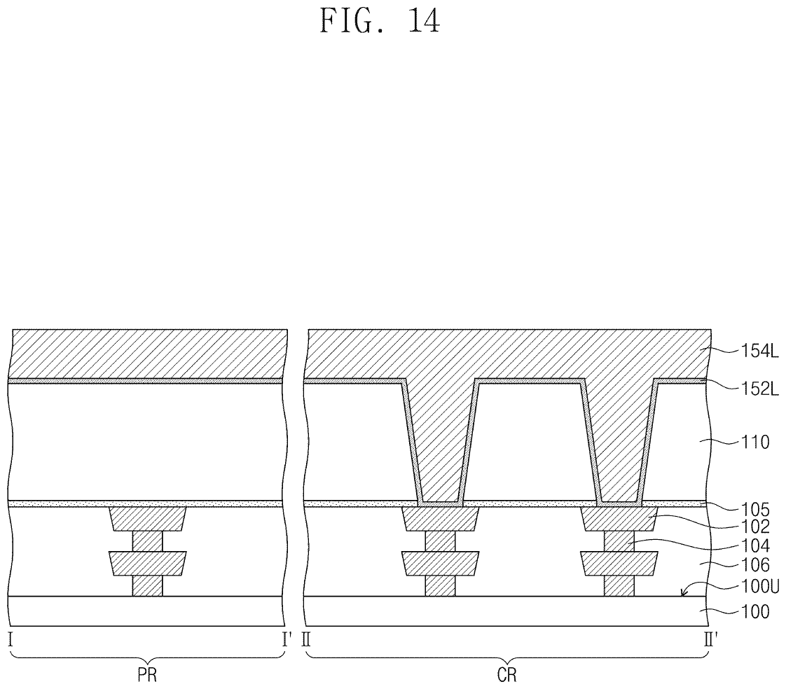

Referring to FIG. 14, a lower contact pattern layer 154L may be formed to fill a remaining portion of the sixth trench TR6. The lower contact pattern layer 154L may be extended to a top surface of the lower barrier pattern layer 152L on the cell and peripheral regions CR and PR. In some example embodiments, the lower contact pattern layer 154L may be formed of or include by a physical vapor deposition (PVD) method. Due to the presence of the second trench TR2, the upper portion of the lower interconnection line 102 may not be recessed, and in the afore-described process of forming the fifth trench TR5, the upper portion of the fifth trench TR5 may be formed to have an increased width, facilitating the formation of the lower contact plug 150. Thus, it may be possible to prevent or reduce the likelihood of and/or the impact from a void from being formed in the lower barrier pattern layer 152L and the lower contact pattern layer 154L. Accordingly, a magnetic memory device with improved electrical and reliability characteristics may be fabricated with high yield.

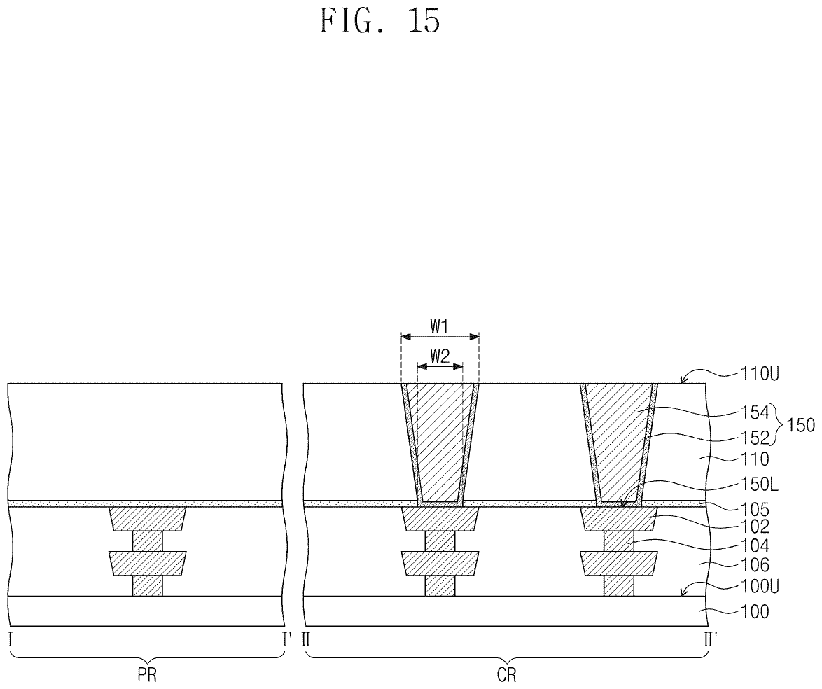

Referring to FIG. 15, the lower contact pattern 154 and the lower barrier pattern 152 may be formed in the second lower interlayer insulating layer 110 on the cell region CR. The lower contact pattern 154 and the lower barrier pattern 152 may be referred to as the lower contact plug 150. Each of the lower contact plugs 150 may penetrate the second lower interlayer insulating layer 110 and the lower insulating layer 105 on the cell region CR and may be electrically connected to a corresponding one of the lower interconnection lines 102. In other words, the bottom surface 150L of the lower contact plug 150 may be in contact with a corresponding one of the uppermost ones of the lower interconnection lines 102. The lower contact plug 150 may have a width in the second and/or third direction D2 or D3, and the first width W1 of the upper portion of the lower contact plug 150 may be larger than the second width W2 of the lower portion of the lower contact plug 150. The lower contact plug 150 may be formed by planarizing the lower contact pattern layer 154L and the lower barrier pattern layer 152L to expose the top surface 110U of the second lower interlayer insulating layer 110. In some example embodiments, the planarization may be achieved through a chemical mechanical polishing (CMP) process.

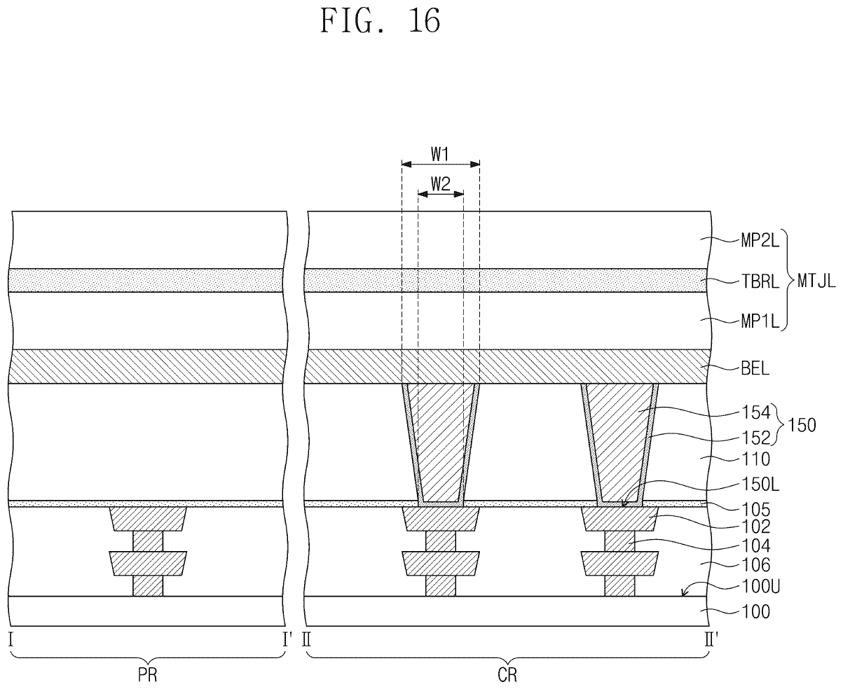

Referring to FIG. 16, a bottom electrode layer BEL and a magnetic tunnel junction layer MTJL may be sequentially formed on the cell and peripheral regions CR and PR and on the second lower interlayer insulating layer 110. In some example embodiments, the magnetic tunnel junction layer MTJL may include a first magnetic layer MP1L, a tunnel barrier layer TBRL, and a second magnetic layer MP2L, which are sequentially stacked on the bottom electrode layer BEL. The magnetic tunnel junction layer MTJL and the bottom electrode layer BEL may be formed by one or more of a sputtering method, a chemical vapor deposition (CVD) method, a physical vapor deposition (PVD) method, or an atomic layer deposition (ALD) method, and may or may not be formed with the same or similar methods.

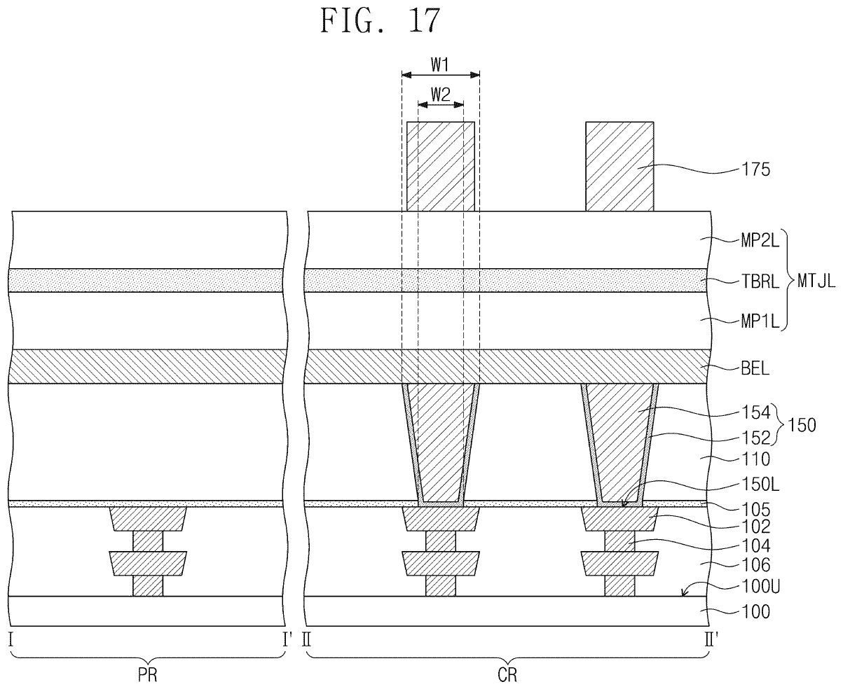

Referring to FIG. 17, a conductive mask pattern 175 may be formed on the cell region CR and on the second magnetic layer MP2L. The conductive mask pattern 175 may define positions and/or shapes of magnetic tunnel junction patterns MTJ to be formed in a subsequent step and may be used as the top electrode TE of the data storage structure DS. The conductive mask pattern 175 may be formed of or include at least one of metallic materials (e.g., Ta, W, Ru, and Ir) or conductive metal nitride materials (e.g., TiN).

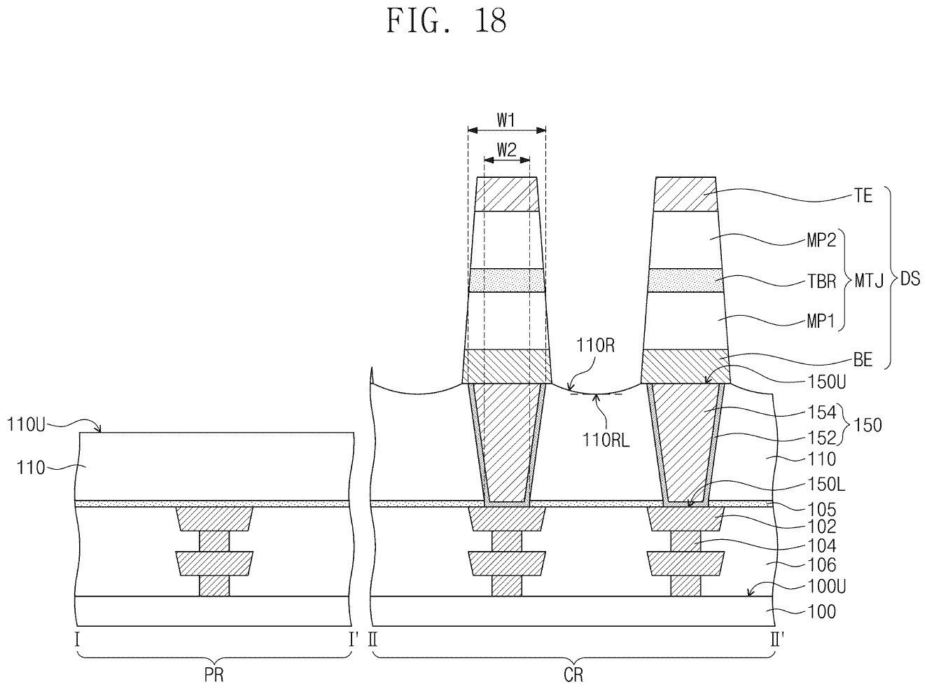

Referring to FIG. 18, the magnetic tunnel junction pattern MTJ and the bottom electrode BE may be formed on the cell region CR. The magnetic tunnel junction pattern MTJ and the bottom electrode BE may be formed by sequentially etching the magnetic tunnel junction layer MTJL and the bottom electrode layer BEL using the conductive mask pattern 175 as an etch mask. The second magnetic layer MP2L, the tunnel barrier layer TBRL, and the first magnetic layer MP1L may be sequentially etched to form the second magnetic pattern MP2, the tunnel barrier pattern TBR, and the first magnetic pattern MP1, respectively. A remaining portion of the conductive mask pattern, which is left on the magnetic tunnel junction pattern MTJ after the etching of the magnetic tunnel junction layer MTJL and the bottom electrode layer BEL, may be referred to as the top electrode TE. The top electrode TE, the magnetic tunnel junction pattern MTJ, and the bottom electrode BE may be referred to as the data storage structure DS.

In various example embodiments, the process of etching the magnetic tunnel junction layer MTJL and the bottom electrode layer BEL may be or may include an ion beam etching process, which is performed using an ion beam. Here, the ion beam may contain ions of inert atoms such as but not limited to argon. An upper portion of the second lower interlayer insulating layer 110 between the data storage structures DS may be recessed by the etching process. As a result, the second lower interlayer insulating layer 110 on the cell region CR may have the recessed portion 110R, which is recessed toward the substrate 100. The lowermost surface 110RL of the recessed portion 110R of the second lower interlayer insulating layer 110 may be located at a height lower than the top surfaces 150U of the lower contact plugs 150. In addition, an upper portion of the second lower interlayer insulating layer 110 on the peripheral region PR may be recessed by the etching process. The top surface 110U of the second lower interlayer insulating layer 110 on the peripheral region PR may be located at a height lower than the lowermost surface 110RL of the recessed portion 110R of the second lower interlayer insulating layer 110 on the cell region CR.

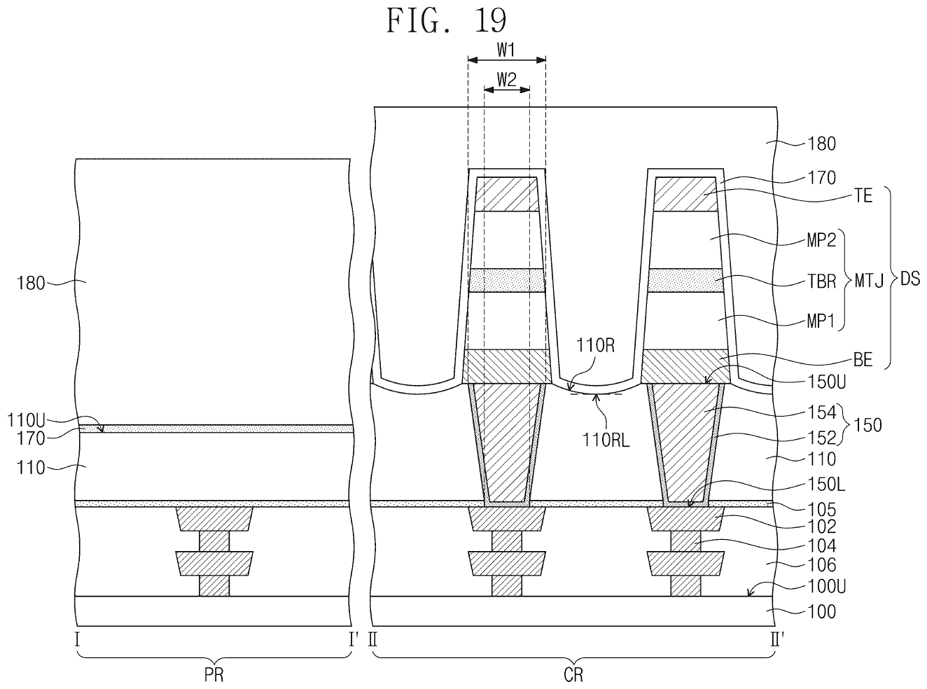

Referring to FIG. 19, the protection insulating layer 170 may be formed on the second lower interlayer insulating layer 110. The protection insulating layer 170 may conformally cover top and side surfaces of the data storage structures DS on the cell region CR and may be extended along the recessed portion 110R of the second lower interlayer insulating layer 110. The protection insulating layer 170 may be extended to a region on the second lower interlayer insulating layer 110 of the peripheral region PR. The upper insulating layer 180 may be formed on the protection insulating layer 170. The upper insulating layer 180 may cover the data storage structures DS and may fill a space between the data storage structures DS. The upper insulating layer 180 may be extended to cover the protection insulating layer 170 on the peripheral region PR.

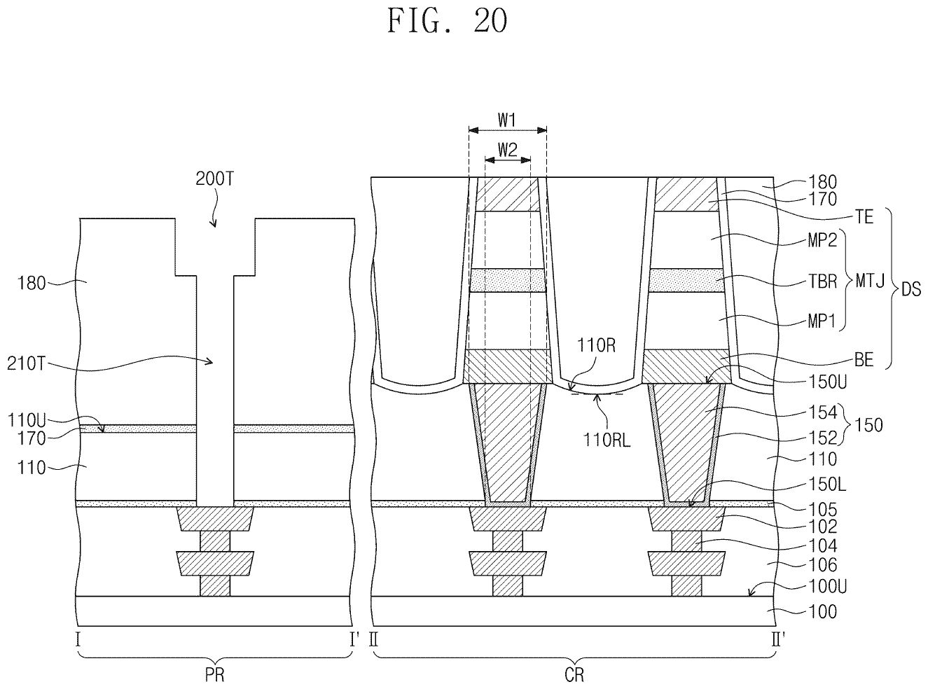

Referring to FIG. 20, the upper insulating layer 180 and the protection insulating layer 170 on the cell region CR may be partially removed to expose a top surface of the top electrode TE of the data storage structure DS. A peripheral interconnection trench 200T and a peripheral contact trench 210T may be formed on the peripheral region PR. The peripheral interconnection trench 200T may be formed in the upper insulating layer 180 to penetrate an upper portion of the upper insulating layer 180. The peripheral contact trench 210T may be extended from a bottom surface of the peripheral interconnection trench 200T toward the substrate 100. The peripheral contact trench 210T may be formed to penetrate not only a lower portion of the upper insulating layer 180 on the peripheral region PR but also the protection insulating layer 170, the second lower interlayer insulating layer 110, and the lower insulating layer 105 on the peripheral region PR, and as a result, the peripheral contact trench 210T may expose a top surface of a corresponding one of the uppermost ones of the lower interconnection lines 102.

Referring back to FIGS. 2 and 3, the upper interconnection line 200, the upper interconnection line contact 210, and the peripheral upper interconnection line 200P may be formed. The upper interconnection line contact 210 may be formed in the peripheral contact trench 210T on the peripheral region PR, and the peripheral upper interconnection line 200P may be formed in the peripheral interconnection trench 200T on the peripheral region PR. The upper interconnection line 200 may be formed on the upper insulating layer 180 on the cell region CR and may cover the exposed top surface of the top electrode TE. Thus, the upper interconnection line 200 may be electrically connected to the top electrode TE. The formation of the upper interconnection line 200, the upper interconnection line contact 210, and the peripheral upper interconnection line 200P may include forming a conductive layer on the upper insulating layer 180 to fill the peripheral interconnection trench 200T and the peripheral contact trench 210T and planarizing the conductive layer to expose the upper insulating layer 180 on the peripheral region PR. The conductive layer on the cell region CR may also be planarized during the planarization process on the conductive layer. As a result of the planarization process, the upper insulating layer 180 and the peripheral upper interconnection line 200P on the peripheral region PR may have top surfaces that are substantially coplanar with each other.

In a magnetic memory device according to various example embodiments, a width of a lower contact plug may be larger near a bottom electrode than near a lower interconnection line. Accordingly, in a metal deposition process to form the lower contact plug, a void may not be formed or may be less likely to be formed in the lower contact plug, and thus, it may be possible to improve the reliability of the magnetic memory device and/or increase a yield in a fabrication process.

In some example embodiment in a method of fabricating a magnetic memory device according to various example embodiments, a dummy pattern may be additionally formed to suppress concentration of etching solution in a process of forming the lower contact plug, and thus, it may be possible to prevent the lower interconnection line from being recessed. Accordingly, in the metal deposition process to form the lower contact plug, a void may not be formed or may be less likely to be formed in the lower contact plug. As a result, it may be possible to realize a magnetic memory device with improved reliability and/or increased the yield in the fabrication process.

While various example embodiments have been particularly shown and described, it will be understood by one of ordinary skill in the art that variations in form and detail may be made therein without departing from the spirit and scope of the attached claims. Additionally example embodiments are not necessarily mutually exclusive with one another. For example, some example embodiments may include one or more features described with reference to one or more figures, and may also include one or more other features described with reference to one or more other figures.

What is claimed is:

1. A magnetic memory device, comprising:
a substrate;
a lower interconnection line on the substrate;
a data storage structure on the lower interconnection line; and
a lower contact plug between the lower interconnection line and the data storage structure and extended in a first direction perpendicular to a top surface of the substrate to connect the lower interconnection line to the data storage structure,
wherein an upper portion of the lower contact plug has a first width in a second direction parallel to the top surface of the substrate,
a lower portion of the lower contact plug has a second width in the second direction, and
the first width is larger than the second width.

2. The magnetic memory device of claim 1, wherein the first width is 1.3 to 1.5 times the second width.

3. The magnetic memory device of claim 1, wherein the data storage structure comprises a bottom electrode, a magnetic tunnel junction pattern, and a top electrode that are sequentially stacked on the lower contact plug.

4. The magnetic memory device of claim 3, wherein the magnetic tunnel junction pattern comprises a first magnetic pattern, a second magnetic pattern, and a tunnel barrier pattern between the first and the second magnetic patterns.

5. The magnetic memory device of claim 1, wherein the lower contact plug comprises:
a lower contact pattern; and
a lower barrier pattern extending along bottom and side surfaces of the lower contact pattern.

6. The magnetic memory device of claim 5, wherein the lower barrier pattern comprises a metal nitride material.

7. The magnetic memory device of claim 1, further comprising:
an upper interconnection line on the data storage structure and connected to the data storage structure.

8. The magnetic memory device of claim 1, wherein a bottom surface of the lower contact plug is in direct contact with the lower interconnection line.

9. The magnetic memory device of claim 1, further comprising:
a first lower interlayer insulating layer on the substrate to cover the lower interconnection line;
a lower insulating layer on the first lower interlayer insulating layer to cover a top surface of the lower interconnection line; and
a second lower interlayer insulating layer on the lower insulating layer,
wherein the lower contact plug penetrates the second lower interlayer insulating layer and the lower insulating layer, and the lower contact plug is connected to the lower interconnection line.

10. The magnetic memory device of claim 9, wherein
the data storage structure is on the second lower interlayer insulating layer,
the second lower interlayer insulating layer has recessed portions at first and second sides of the data storage structure, and
the lowermost surface of the recessed portion of the second lower interlayer insulating layer is below a top surface of the lower contact plug.

11. The magnetic memory device of claim 10, wherein
the substrate comprises a cell region and a peripheral region,
the lower interconnection line, the lower contact plug, the data storage structure, and upper interconnection line are on the cell region,
the first and second lower interlayer insulating layers and the lower insulating layer cover the cell region and the peripheral region, and
a top surface of the second lower interlayer insulating layer on the peripheral region is lower than the lowermost surface of the recessed portion of the second lower interlayer insulating layer on the cell region.

12. A method of fabricating a magnetic memory device, comprising:
providing a substrate including a cell region and a peripheral region;
forming a lower interconnection line on the substrate and a first lower interlayer insulating layer covering the lower interconnection line;
sequentially forming a lower insulating layer, a second lower interlayer insulating layer, a first hard mask layer, and a second hard mask layer on the first lower interlayer insulating layer and the lower interconnection line;
forming a first trench on the cell region to penetrate the second hard mask layer and the first hard mask layer;
forming a second trench on the peripheral region to penetrate the second hard mask layer and an upper portion of the first hard mask layer, a bottom surface of the second trench being located at a height higher than a bottom surface of the first trench;
etching the second lower interlayer insulating layer, which is exposed by the first trench, on the cell region to form a third trench penetrating the second lower interlayer insulating layer; and
partially and laterally etching an upper portion of the second lower interlayer insulating layer, which is exposed by an inner side surface of the third trench, to form a fourth trench,
wherein the bottom surface of the second trench is in the first hard mask layer, after the forming of the fourth trench.

13. The method of claim 12, wherein the first hard mask layer comprises a metal nitride material.

14. The method of claim 12, further comprising:
removing the upper portion of the first hard mask layer to remove the second trench from the peripheral region;
laterally etching a portion of the second lower interlayer insulating layer exposed by an inner side surface of the fourth trench to form a fifth trench;
etching the lower insulating layer, which is exposed by the fifth trench, to form a sixth trench;
removing a remaining portion of the first hard mask layer; and
forming a lower contact plug in the sixth trench,
wherein an upper portion of the lower contact plug has a first width in a second direction parallel to a top surface of the substrate,
a lower portion of the lower contact plug has a second width in the second direction, and
the first width is larger than the second width.

15. The method of claim 14, wherein the first width is 1.3 to 1.5 times the second width.

16. The method of claim 14, wherein the lower contact plug comprises:
a lower contact pattern; and
a lower barrier pattern extended along bottom and side surfaces of the lower contact pattern.

17. The method of claim 12, wherein the second trench on the peripheral region are formed in plural.

18. The method of claim 14, further comprising:
forming a bottom electrode layer and a magnetic tunnel junction layer on the second lower interlayer insulating layer and the lower contact plug;
forming a conductive mask pattern on the magnetic tunnel junction layer on the cell region; and
etching the magnetic tunnel junction layer and the bottom electrode layer using the conductive mask pattern as an etch mask to form a data storage structure.

19. The method of claim 18, wherein the etching of the magnetic tunnel junction layer and the bottom electrode layer comprises recessing a top surface of the second lower interlayer insulating layer at first and second sides of the data storage structure.

20. The method of claim 18, further comprising:
forming a protection insulating layer to cover the data storage structure and the second lower interlayer insulating layer;
forming an upper insulating layer on the protection insulating layer;
etching a portion of the upper insulating layer and a portion of the protection insulating layer on the cell region to expose a top surface of a top electrode; and
forming an upper interconnection line connected to the top electrode.
